(19) United States
(12) Patent Application Publication
(10) Pub. No.: US 2018/0219167 A1
(43) Pub. Date: Aug. 2, 2018

(54) FLEXIBLE QUANTUM DOT LIGHT-EMITTING DIODE AND METHOD FOR MANUFACTURING THE SAME

(71) Applicant: Shenzhen China Star Optoelectronics Technology Co., Ltd., Shenzhen, Guangdong (CN)

(72) Inventor: Chao Xu, Shenzhen, Guangdong (CN)

(73) Assignee: Shenzhen China Star Optoelectronics Technology Co., Ltd., Shenzhen, Guangdong (CN)

(21) Appl. No.: 15/500,187

(22) PCT Filed: Jan. 19, 2017
(86) PCT No.: PCT/CN2017/071634

§ 371 Date: Oct. 5, 2017

(30) Foreign Application Priority Data
Nov. 28, 2016 (CN) 201611077586.7

(51) Int. Cl. H01L 51/50; H01L 51/00; H01L 51/52; H01L 51/56; H01L 33/06

(52) U.S. Cl. CPC H01L 51/502; H01L 51/0097; H01L 51/5206; H01L 33/06; H01L 51/5056; H01L 51/56; H01L 51/5221

(57) ABSTRACT

Disclosed is a flexible quantum dot light-emitting diode, including a substrate, an anode layer, a hole-transporting layer, a quantum dot light-emitting layer, an electron-outputting layer, and a cathode layer, arranged from the bottom up. The anode layer is made of PEDOT:PSS material. Metal nanoparticles are provided between the anode layer and the substrate. The flexible quantum dot light-emitting diode can significantly increase luminous efficiency of devices.

### CROSS-REFERENCE TO RELATED APPLICATIONS

The present application claims the priority of Chinese patent application CN 201611077586.7, entitled “Flexible quantum dot light-emitting diode and method for manufacturing the same” and filed on Nov. 28, 2016, the entirety of which is incorporated herein by reference.

### FIELD OF THE INVENTION

The present disclosure relates to the technical field of light-emitting devices, and in particular, to a flexible quantum dot light-emitting diode and a method for manufacturing the same.

### BACKGROUND OF THE INVENTION

A quantum dot light-emitting diode (hereinafter referred to as QLED) can show three-primary colors (RGB) by means of different sizes of particles and voltage. Due to this, a QLED theoretically has a longer service life and a better color expression than an organic light-emitting diode (hereinafter referred to as OLED). In the meanwhile, a QLED can save at most 50% of energy. It consumes only about 1/10 of the energy a liquid crystal substrate requires at present. Having a higher efficiency of electron-to-photon conversion, a QLED consumes less energy with same screen luminance. Thanks to these advantages. QLEDs are praised as a new generation of illumination display technology after OLEDs.

Film formation of quantum dot light-emitting layers used to produce QLED devices is generally realized through a solution method. Thus, the QLED has apparent advantages in flexible display. At present, main material used in conductive anodes is ITO, which has advantages of low price, high transmittance, low electrical resistivity, etc. However, with regard to ITO, In is a rare element and its storage volume in the world is small. In₂O₃ content in the film is high and thus a high cost is required. Besides, ITO material is fragile and periodic bending or compression thereof will easily result in cracks, which leads to conductivity failure in a display device. Besides, there is comparatively high surface resistance and roughness when the ITO material is deposited on its matched substrate under low temperature. Thus, it is necessary to find a new conductive anode material to replace ITO anodes. Yet, other high-conductivity anode materials are not maturely developed, which imposes restrictions on development of flexible QLED display devices.

### SUMMARY OF THE INVENTION

To solve the above-mentioned technical problems, the present disclosure provides anew flexible quantum dot light-emitting diode (hereinafter referred to as QLED). The new flexible QLED uses PEDOT:PSS as an anode material and forms a layer of metal nanoparticles between an anode layer and a substrate, which effectively solves the problem of low electrical conductivity in existing flexible anodes and significantly increases luminous efficiency of a QLED.

According to one aspect of the present disclosure, a flexible QLED is provided. The QLED comprises a substrate, an anode layer, a hole-transporting layer, a quantum dot light-emitting layer, an electron-outputting layer, and a cathode layer, arranged from the bottom up. The anode layer is made of PEDOT:PSS material. Metal nanoparticles are provided between the anode layer and the substrate.

According to one preferred embodiment of the present disclosure, a material of the substrate is one or more selected from a group consisting of PET, PEEK, PC, PES, PAR, and PI. Preferably, a material of the substrate is PET, PI or combination of the two.

According to one preferred embodiment of the present disclosure, the metal nanoparticles are one or more selected from Au particles, Ag particles, and Al particles. Preferably, the metal nanoparticles are from Au particles and/or Ag particles.

According to one preferred embodiment of the present disclosure, the metal nanoparticles are dispersed as a monolayer between the anode layer and the substrate.

According to one preferred embodiment of the present disclosure, the metal nanoparticles come in a shape of a sphere or a cuboid, with a size of 5-20 nm. The metal nanoparticles are arranged at intervals of 10-40 nm. The metal nanoparticles are arranged in good order and are not continuous, so that they can have good transmission of light.

According to one preferred embodiment of the present disclosure, the anode layer has a thickness of 40-60 nm.

According to one preferred embodiment of the present disclosure, the anode layer is made of PEDOT:PSS material (including modified or doped PEDOT:PSS material). Doping is to add certain high-conductivity materials, such as graphene, in PEDOT:PSS. Modification is to improve electrical conductivity through modifying the type of functional groups in macromolecular structure. PEDOT:PSS is one kind of high-polymer aqueous solution, comprised of PEDOT and PSS. PEDOT is a polymer of EDOT and PSS is polystyrene sulphonate.

According to another aspect of the present disclosure, a method for manufacturing a flexible QLED is provided. The method comprises the following steps.

In Step 1, a substrate is provided and a layer of metal nanoparticles with a moderate density is formed thereon.

In Step 2, an anode layer is formed on the metal nanoparticles.

In Step 3, a hole-transporting layer, a quantum dot light-emitting layer, and an electron-outputting layer are successively formed on the anode layer and finally a metallic cathode is formed through evaporation.

The above-mentioned anode layer is made of PEDOT:PSS material.

According to one preferred embodiment of the present disclosure, the layer of metal nanoparticles in Step 1 is formed through evaporation, sputtering, spin coating or ink-jet printing, etc.

According to one preferred embodiment of the present disclosure, the anode layer in Step 2 and the hole-transporting layer, the quantum dot light-emitting layer, and the electron-outputting layer in Step 3 are formed through spin coating.

The present disclosure achieves the following beneficial effects.

In the present disclosure, PEDOT:PSS is used as anode material of the flexible QLED, so as to ensure flexibility of display devices. In the meanwhile, metal nanoparticles are provided between the flexible substrate and the PEDOT:PSS anode layer, which can not only significantly improve electrical conductivity of the PEDOT:PSS anode layer, but also significantly increase luminous efficiency of devices by taking advantage of surface plasmon resonance effect and surface scattering effect of heavy metal. The heavy metal nanoparticles in the present disclosure, with a moderate thickness, are arranged in good order and are not continuous, so that they can have good transmission of light.

### BRIEF DESCRIPTION OF THE DRAWINGS

The drawings are provided for further understanding of the present disclosure, and constitute one part of the description. They serve to explain the present disclosure in conjunction with the embodiments, rather than to limit the present disclosure in any manner. In the drawings:

FIG. 1 schematically shows structure of a flexible QLED in the present disclosure.

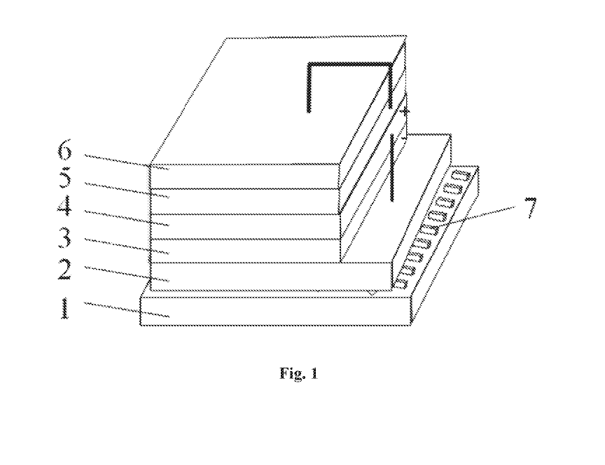

### DETAILED DESCRIPTION OF THE EMBODIMENTS

The present disclosure will be explained in detail with reference to the embodiments. However, the present disclosure is not limited by the following embodiments.

### Embodiment 1

A flexible QLED is provided. The QLED comprises a substrate 1, an anode layer 2, a hole-transporting layer 3, a quantum dot light-emitting layer 4, an electron-outputting layer 5 and a cathode layer 6, arranged from the bottom up. The anode layer 2 is made of PEDOT:PSS material (comprising modified or doped PEDOT:PSS material) and the substrate is made of PET material. Metal nanoparticles 7 are provided between the anode layer and the substrate, so as to improve electrical conductivity of and increase luminous efficiency of the anode layer. Metal nanoparticles 7 are Au particles. Dispersed as a monolayer between the substrate and the anode layer, the metal nanoparticles come in a shape of a sphere or a cuboid, with a size of 5-20 nm. There is an interval of 1-2 metal nanoparticles (about 10-40 nm) between each two metal nanoparticles. The metal nanoparticles are arranged in good order and are not continuous, so that they can have good transmission of light. The anode layer 2 has a thickness of 40-60 nm.

A method for manufacturing a flexible QLED comprises the following steps. Firstly, a layer of metal nanoparticles 7 with a moderate density is formed on a substrate through evaporation, sputtering, spin coating or ink-jet printing, etc. The metal nanoparticle 7 has a size of 5-20 nm. Then, a PEDOT:PSS anode layer with a thickness of 40-60 nm is formed on the layer of metal nanoparticles through spin coating, etc. Next, a hole-transporting layer 3, a quantum dot light-emitting layer 4, and an electron-outputting layer 5 are successively formed on the PEDOT:PSS anode layer through spin coating, etc. Finally, a metallic cathode is formed through evaporation.

### Embodiment 2

A flexible QLED is provided. The QLED comprises a substrate 1, an anode layer 2, a hole-transporting layer 3, a quantum dot light-emitting layer 4, an electron-outputting layer 5 and a cathode layer 6, arranged from the bottom up. The anode layer is made of PEDOT:PSS material (comprising modified or doped PEDOT:PSS material) and the substrate 1 is made of PI material. Metal nanoparticles 7 are provided between the anode layer 2 and the substrate 1, so as to improve electrical conductivity of and increase luminous efficiency of the anode layer. Metal nanoparticles 7 are Ag particles. Dispersed as a monolayer between the substrate 1 and the anode layer 2, the metal nanoparticles 7 come in a shape of a sphere or a cuboid, with a size of 5-20 nm. There is an interval of 1-2 metal nanoparticles (about 10-40 nm) between each two metal nanoparticles 7. The metal nanoparticles are arranged in good order and are not continuous, so that they can have good transmission of light. The anode layer has a thickness of 40-60 nm.

A method for manufacturing a flexible QLED is identical with that provided in Embodiment 1.

The present disclosure is illustrated in detail in combination with embodiments hereinabove, but it can be understood that the embodiments disclosed herein can be improved without departing from the protection scope of the present disclosure. The present disclosure is not limited by the specific embodiments disclosed herein, but includes all technical solutions falling into the protection scope of the claims.

### DESCRIPTION OF THE REFERENCE SIGNS

1 substrate
2 anode layer
3 hole-transporting layer
4 quantum dot light-emitting layer
5 electron-outputting layer
6 cathode layer
7 metal nanoparticles

1. A flexible quantum dot light-emitting diode, comprising a substrate, an anode layer, a hole-transporting layer, a quantum dot light-emitting layer, an electron-outputting layer, and a cathode layer, arranged from the bottom up,
wherein the anode layer is made of PEDOT:PSS material, and
wherein metal nanoparticles are provided between the anode layer and the substrate.

2. The light-emitting diode according to claim 1, wherein the metal nanoparticles are one or more selected from Au particles, Ag particles, and Al particles.

3. The light-emitting diode according to claim 1, wherein the metal nanoparticles are dispersed as a monolayer between the anode layer and the substrate.

4. The light-emitting diode according to claim 2, wherein the metal nanoparticles are dispersed as a monolayer between the anode layer and the substrate.

5. The light-emitting diode according to claim 1, wherein the metal nanoparticles come in a shape of a sphere or a cuboid, with a size of 5-20 nm.

6. The light-emitting diode according to claim 2, wherein the metal nanoparticles come in a shape of a sphere or a cuboid, with a size of 5-20 nm.

7. The light-emitting diode according to claim 1, wherein the metal nanoparticles are arranged at intervals of 10-40 nm.

8. The light-emitting diode according to claim 2, wherein the metal nanoparticles are arranged at intervals of 10-40 nm.

9. The light-emitting diode according to claim 1, wherein a material of the substrate is one or more selected from a group consisting of PET, PEEK, PC, PES, PAR, and PI.

10. The light-emitting diode according to claim 1, wherein the anode layer has a thickness of 40-60 nm.

11. A method for manufacturing a flexible quantum dot light-emitting diode, comprising the following steps:
Step 1: providing a substrate and forming thereon a layer of metal nanoparticles with a moderate density;
Step 2: forming an anode layer on the metal nanoparticles; and
Step 3: forming successively on the anode layer a hole-transporting layer, a quantum dot light-emitting layer, and an electron-outputting layer, and finally forming a metallic cathode through evaporation,
wherein the anode layer is made of PEDOT:PSS material.

12. The manufacturing method according to claim 11, wherein the metal nanoparticles are one or more selected from Au particles, Ag particles, and Al particles.

13. The manufacturing method according to claim 11, wherein the metal nanoparticles are dispersed as a monolayer between the anode layer and the substrate.

14. The manufacturing method according to claim 11, wherein the metal nanoparticles come in a shape of a sphere or a cuboid, with a size of 5-20 nm.

15. The manufacturing method according to claim 11, wherein the metal nanoparticles are arranged at intervals of 10-40 nm.

16. The manufacturing method according to claim 11, wherein a material of the substrate is one or more selected from a group consisting of PET, PEEK, PC, PES, PAR, and PI.

17. The manufacturing method according to claim 11, wherein the anode layer has a thickness of 40-60 nm.

18. The manufacturing method according to claim 11, wherein the layer of metal nanoparticles is formed through evaporation, sputtering, spin coating or ink-jet printing.

19. The manufacturing method according to claim 11, wherein the anode layer, the hole-transporting layer, the quantum dot light-emitting layer, and the electron-outputting layer are formed through spin coating.
